(19) United States
(12) Patent Application Publication
(10) Pub. No.: US 2019/0361086 A1
(43) Pub. Date: Nov. 28, 2019

(54) METHOD AND APPARATUS FOR IMPLEMENTING A MAGNETIC RESONANCE MEASUREMENT THAT IS INSENSITIVE TO OFF-RESONANCE

(71) Applicant: Siemens Healthcare GmbH, Erlangen (DE)

(72) Inventors: Mathias Nittka, Baiersdorf (DE); Gregor Koerzdoerfer, Erlangen (DE); Peter Speier, Erlangen (DE); Thomas Kluge, Hirschaid (DE)

(73) Assignee: Siemens Healthcare GmbH, Erlangen (DE)

(21) Appl. No.: 16/420,261

(22) Filed: May 23, 2019

(30) Foreign Application Priority Data
May 25, 2018 (EP) 18174359

(51) Int. Cl. G01R 33/565; G01R 33/34; G01R 33/36

(52) U.S. Cl. CPC G01R 33/56572; G01R 33/36; G01R 33/34

(57) ABSTRACT

In a magnetic resonance method and apparatus, each repetition of a multi-repetition scan, (a) an RF excitation pulse is applied to the subject under examination, (b) a slice-selection gradient is activated while the RF excitation pulse is being applied, (c) further gradients for spatial encoding are activated, and (d) measurement data are acquired as an echo signal produced after the RF excitation pulse. Steps (a) to (d) are repeated until a desired number of RF excitation pulses have been applied. An additional dedicated dephasing gradient is switched in each case such that a transverse magnetization of the spins to be excited by an RF excitation pulse is sufficiently dephased before each applied RF excitation pulse.

### BACKGROUND OF THE INVENTION

### Field of the Invention

The invention concerns a magnetic resonance measurement (data acquisition) that is insensitive to off-resonance, in particular for use in slice-selective magnetic resonance fingerprinting.

### Description of the Prior Art

Magnetic resonance (MR) is a known modality that can be used to generate images of the interior of a subject under examination. In simple terms, this is done by placing the subject under examination in a magnetic resonance scanner in a strong static, homogeneous basic magnetic field, also called the B0 field, at field strengths of 0.2 Tesla to 7 Tesla and higher. This causes the nuclear spins of the subject to be oriented along the basic magnetic field. Radio-frequency excitation pulses (RF pulses) are applied to the subject under examination in order to induce nuclear spin resonances, which causes RF signals, called MR signals to be emitted. The MR signals are detected as raw data, which are entered into a memory as k-space data. The k-space data are used as the basis for reconstructing MR images or obtaining spectroscopic data. Rapidly switched magnetic gradient fields are superimposed on the basic magnetic field in order to spatially encode the measurement data. The recorded measurement data are digitized and stored as complex numerical values in a k-space matrix. A multidimensional Fourier transform, for example, can be used to reconstruct an associated MR image from the k-space matrix, which is populated with values, as described above.

Magnetic resonance imaging by the operation of a magnetic resonance system can be used to determine an existence and/or distribution of a material located inside the subject under examination. For example, this material may be tissue, possibly pathological tissue, of the subject under examination, or a contrast agent, a tracer, or a metabolite.

Information about the materials that are present can be obtained from the acquired measurement data in many different ways. A relatively simple information source, for instance, are the image data reconstructed from the measurement data. There are also more complex methods for obtaining information about the examined subject, for instance from pixel-time series of image data reconstructed from successively measured measurement datasets.

Quantitative MR imaging techniques can be used to determine absolute properties of the measured subject, for instance the tissue-specific T1 relaxation and T2 relaxation in humans. In contrast with these techniques, the conventional sequences mostly used in clinical practice produce only a relative signal intensity for different tissue types (known as weightings), with the result that the diagnostic interpretation is largely based on a subjective assessment by a radiologist. Quantitative techniques thus offer the significant advantage of allowing an objective comparison, but because of the long measurement times associated therewith, they are not widely used currently in routine practice.

More recent quantitative measurement methods, such as magnetic resonance fingerprinting (MRF) methods, could reduce the disadvantage of long measurement times to an acceptable level. In MRF methods, signal evolutions of image data reconstructed from measurement data acquired successively in time using different acquisition parameters are compared, using pattern recognition techniques, with signal evolutions from a previously obtained database of signal evolutions that are characteristic of specific materials (known as the “dictionary”). The materials represented in the image data reconstructed from the measurement data, or the spatial distribution of tissue-specific parameters (such as the transverse relaxation T2 or the longitudinal relaxation T1; known as T1 and T2 maps), can be determined from this comparison. The signal evolutions contained in such a dictionary may have been generated by simulations. The principle of this method is thus to compare measured signal evolutions with a multiplicity of signal evolutions known in advance. In this method, signal evolutions may have been determined for the dictionary for different combinations of T1 and T2 relaxation times. The T1 and T2 times of a pixel in the image are then determined by comparing the measured signal evolution with all the simulated signal evolutions. This process is known as “matching”. The signal evolution in the dictionary that is most similar to the measured signal evolution determines the relaxation parameters T1 and T2 of the particular pixel.

As examples, the article by Ma et al., “Magnetic Resonance Fingerprinting”, Nature, 495: p. 187-192 (2013) and the article by Jiang et al., “MR Fingerprinting Using Fast Imaging with Steady State Precession (FISP) with Spiral Readout”, Magnetic Resonance in Medicine 74: p. 1621-1631 (2015) disclose magnetic resonance fingerprinting methods.

In principle, every echo technique in combination with any method of k-space sampling (Cartesian, spiral, radial) can be used for MRF methods.

At present, a “Fast Imaging with Steady-state Precession” (FISP) sequence in combination with spiral sampling is preferably used, as described, for example, in the cited article by Jiang et al. In such a FISP sequence, after an adiabatic 180° RF inversion pulse, which is designed to deliberately upset the equilibrium state of the spins, is applied a series of RF excitation pulses having pseudo-random flip angles, a separate spiral k-space trajectory is used to read out each echo that results after each of the RF excitation pulses. In such a sequence, n RF excitation pulses are used, which produce the same number of echoes. An individual image is reconstructed from the measurement data acquired along each k-space trajectory. A signal evolution for each pixel is extracted from the n individual images and is compared with the simulated evolutions. The time interval TR between two successive RF excitation pulses of the n RF excitation pulses can be varied in this procedure, for instance in a pseudo-random manner.

FISP sequences, which are also known as GRASS (“Gradient Recalled Acquisition into Steady State”) or T2-FFE (“Fast Field Echo, T2-weighted”) sequences, prove far less sensitive to variations in the static magnetic field B0 compared with TrueFISP sequences, in which the slice-selection gradients are balanced (i.e. the zeroth moment of the slice-selection gradients is zero). This was the primary reason why the FISP-MRF implementation superseded the “original” TrueFISP-based TrueFISP MRF that was described in the article by Ma et al. cited above. Due to the unbalanced gradient moments within each TR, i.e. between two successive RF excitation pulses, it is assumed in FISP-MRF that the magnetization is fully dephased before a subsequent RF excitation pulse flips the magnetization. The above-cited article by Jiang et al. states that the dephasing moment produced by the unbalanced slice-selection gradient used in the article is sufficient for a B0-dependence of the measured echo signal to be negligible.

### SUMMARY OF THE INVENTION

An object of the invention is to facilitate MRF measurements so as to produce results that are independent of off-resonances.

The invention is based on the following findings.

As explained further below with reference to FIGS. 1 to 3, it has been found that it is not always the case, as previously assumed, that the transverse magnetization is fully dephased by unbalanced gradient moments as are used in slice-selection (2D) FISP methods. It has been found instead that for slice-selective (2D) MRF methods, signal modulations caused by off-resonance arise that may significantly distort the results of MRF methods, and hence a non-negligible B0 dependence does exist. It has also been found that in order to avoid this B0-dependence, it is not sufficient to bring about “just any” further dephasing of the transverse magnetization, but instead dedicated dephasing is necessary to avoid artifacts in the results.

A method according to the invention for generating measurement data from a subject under examination by means of magnetic resonance technology has the steps that are performed within each repetition of a multi-repetition scan. Within each repetition,
(a) an RF excitation pulse is applied to the subject under examination,
(b) a slice-selection gradient is activated while the RF excitation pulse is being applied,
(c) further gradients for spatial encoding are activated,
(d) measurement data are acquired an echo signal produced after the RF excitation pulse.

Steps (a) to (d) are repeated until a desired number of RF excitation pulses have been applied.

An additional dedicated dephasing gradient is activated that dephases a transverse magnetization of the spins to be excited by an RF excitation pulse, before each applied RF excitation pulse.

The activation of dedicated dephasing gradients according to the invention avoids a B0-dependence of the acquired measurement data. Dedicated dephasing gradients thus can avoid dependence on off-resonances, as occurs in particular when inhomogeneities in the B0 field arise, while also being designed so as not to produce diffusion effects. In this process, the dedicated dephasing gradient ensures that the spins to be excited by an RF excitation pulse are sufficiently dephased before each applied RF excitation pulse, so that at the time of excitation by an RF excitation pulse, components of a preceding transverse magnetization that may still persist are at most negligible. In particular, the dedicated dephasing gradients completely dephase the spins.

The echo signals, which are acquired as the measurement data, can be produced in accordance with a FISP sequence scheme. The FISP sequence is already frequently used for MRF methods, and can be modified without great effort so as to include dedicated dephasing gradients according to the invention.

Dedicated dephasing gradients according to the invention can be determined by simulations, in particular Bloch simulations, for instance by comparing the performance of different dephasing-gradient candidates while varying selected off-resonances. Simulations can be performed economically and require neither the use of a magnetic resonance system nor a real subject under examination.

Dedicated dephasing gradients determined by such a simulation can additionally be verified experimentally, e.g. using phantoms or on persons under examination, and, for instance should satisfactory results still not have been achieved, can be modified. These verification can be performed especially in cases in which the simulated conditions differ unduly from the actual measurement conditions. These verification can also help to improve the simulation.

It is also possible to determine the dedicated dephasing gradients purely experimentally, for instance by again comparing the performance of different dephasing-gradient candidates while varying an off-resonance used in the measurement. Dedicated dephasing gradients obtained in this way are particularly well adapted to the actual conditions of the magnetic resonance system on which they were determined.

This comparison of simulations or experimental results can employ, for example, an optimization technique in order to find the optimum dedicated dephasing gradient using the results from the dephasing-gradient candidates. The optimization technique determines the dephasing gradient that achieves the lowest B0-dependence of the measurement data, if applicable taking into account the resultant loads placed on the gradient system.

A magnetic resonance apparatus according to the invention has an MR data acquisition scanner that has a basic field magnet, a gradient unit, a radio-frequency unit, and a control computer designed to implement the method according to the invention, and having a radio-frequency transmit/receive controller that includes a multiband RF pulse unit.

The present invention also encompasses a non-transitory, computer-readable data storage medium encoded with programming instructions that, when the storage medium is loaded into a computer or computer system of an magnetic resonance apparatus, cause the computer or computer system to operate the magnetic resonance apparatus so as to implement any or all embodiments of the method according to the invention, as described above.

The advantages and comments described above with regard to the method apply analogously also to the magnetic resonance apparatus and to the electronically readable data storage medium.

### BRIEF DESCRIPTION OF THE DRAWINGS

FIG. 1 shows, as a comparison, examples of results of parameter values obtained by MRF, which are based on an image series that was generated using different off-resonances and with and without additional dephasing gradients.

FIGS. 2a-2d show, as a comparison, examples of simulations of a transverse magnetization using different off-resonances and with and without a dedicated dephasing gradient.

FIG. 3 shows effects of different additional dephasing gradients.

FIG. 4 is a schematic flowchart of the method according to the invention.

FIG. 5 shows an example of a pulse sequence that can be used for the method according to the invention.

FIG. 6 shows a larger portion of a more general pulse sequence that can be used for the method according to the invention.

FIG. 7 is a schematic illustration of a magnetic resonance apparatus according to the invention.

### DESCRIPTION OF THE PREFERRED EMBODIMENTS

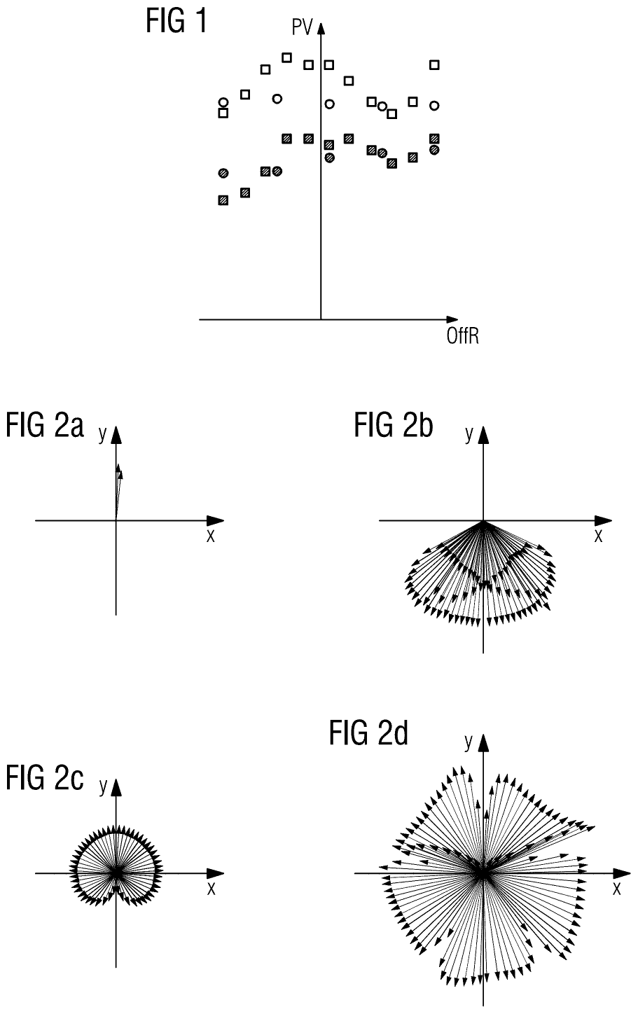

FIG. 1 shows as a comparison, examples of results of parameter values PV, e.g. T1 or T2 values, obtained by MRF, which are based on an image series that was generated using different off-resonances OffR and with and without additional dedicated dephasing gradients during acquisition of the measurement data.

The values represented by squares have been obtained here by MRF methods based on image series that were reconstructed from measurement data that corresponds to echo signals that were read out without additional dedicated dephasing gradients; the values represented by circles are based on measurement data acquired using an additional dedicated dephasing gradient. The values shown shaded are obtained from one region of interest (ROI) of the subject under examination; the values shown unshaded are obtained from another ROI of the subject under examination.

It is evident that in each of the ROIs represented, the parameter values obtained that are based on measurement data acquired without additional dephasing gradients (squares) using different off-resonances vary significantly more than those based on measurement data measured with an additional dephasing gradient (circles).

Thus FIG. 1 illustrates the dependence of the measurement data on off-resonances that actually exists when the measurement data is acquired without additional dephasing gradients, and hence the off-resonance dependence of the parameter values PV obtained on this basis. Such off-resonances arise unintentionally in real systems as a result of inhomogeneities in the B0 field, because the locally prevailing B0 field is directly proportional to the resonant frequency of the local spins.

The dephasing gradient at which the parameter values PV, obtained on the basis of the measurement values, no longer exhibit as far as possible any dependence on off-resonances OffR, can be obtained by testing (by simulation or experimentally) different additional dephasing gradients.

FIGS. 2a, 2b, 2c and 2d show, as a comparison, examples of simulations of a transverse magnetization using different off-resonances and with and without a dedicated dephasing gradient.

The left side (2a and 2c) shows the simulated transverse magnetization at the time of a first RF excitation pulse of a total of N RF excitation pulses; the right side (2b and 2d) shows for comparison the simulated transverse magnetization at the time of a 500th RF excitation pulse of a total of N RF excitation pulses in N repetitions.

At the top (2a and 2b), the transverse magnetization was simulated without additional dedicated dephasing gradients; at the bottom (2c and 2d), the simulation included an additional dedicated dephasing gradient.

It is evident that the transverse magnetization without additional dedicated dephasing gradients is not evenly distributed back at the first RF excitation pulse (a mean transverse magnetization in the y-direction can be seen in the example) and even at later RF excitation pulses, with the result that the magnetization does not cancel out on average but instead a non-zero average transverse magnetization is produced. This again illustrates that without dedicated dephasing gradients, the transverse magnetization at the excitation times when the RF excitation pulses are applied is not zero as previously assumed. In comparison, the transverse magnetization with additional dephasing gradients is distributed clearly more evenly, with the result that the transverse magnetization disappears on average.

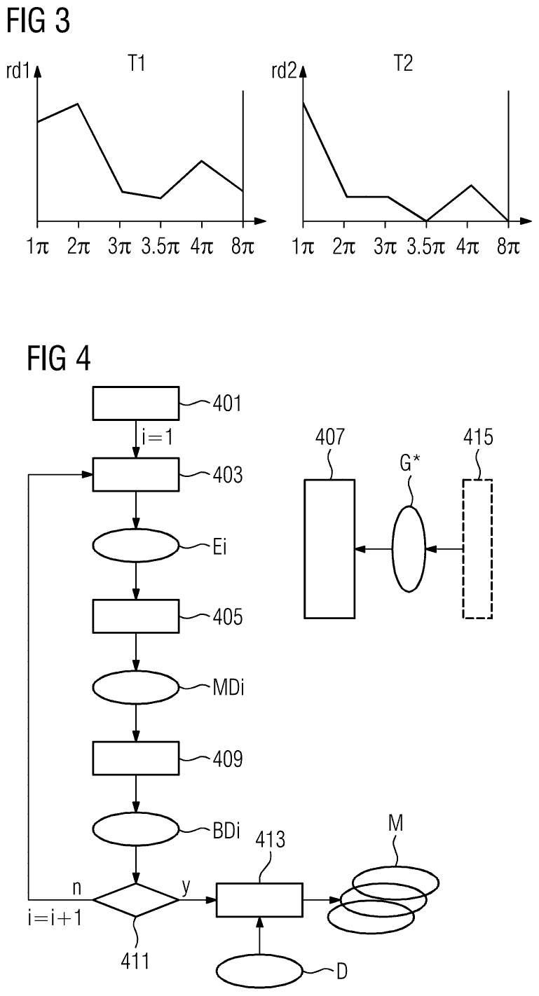

FIG. 3 shows effects of different additional dephasing gradients.

On the left side are depicted relative deviations rd1 of T1 parameter values generated by MRF, which relative deviations have been obtained from five trials using five different off-resonances in each case, and have each been generated on the basis of measurement values measured using different dephasing gradients having dephasing moments of between 1π and 8π (abscissa).

On the right side are likewise depicted relative deviations rd2 of T2 parameter values generated by MRF, which relative deviations have been obtained from five trials using five different off-resonances in each case, and have each been generated on the basis of measurement values measured using different dephasing gradients having dephasing moments of between 1π and 8π (abscissa).

The smaller the relative deviation rd1 and/or rd2, the lower the effect of the used off-resonances on the result, and the less dependent on the B0 field were the underlying measurement values.

A fundamental trend of a relative deviation rd1 and/or rd2 decreasing with increasing gradient moment can be identified in both cases. This trend does not proceed monotonically as expected, however. Instead, using a dephasing gradient having a gradient moment of 3.5π achieved a B0-independence of comparable quality to that achieved using a dephasing gradient having a gradient moment of 8π.

Dedicated dephasing gradients should be determined such that they allow the measurement values to have minimum possible dependence on off-resonances. At the same time, they should be designed such that as far as possible they produce no diffusion effects, i.e. in particular that they have minimum possible gradient moments.

Thus in the example shown in FIG. 3, using the stated conditions, it would be possible to determine a dephasing gradient having a gradient moment of 3.5π to be the dedicated dephasing gradient according to the invention to be used.

FIG. 4 is a schematic flowchart of the method according to the invention for generating measurement data from a subject under examination by means of magnetic resonance technology.

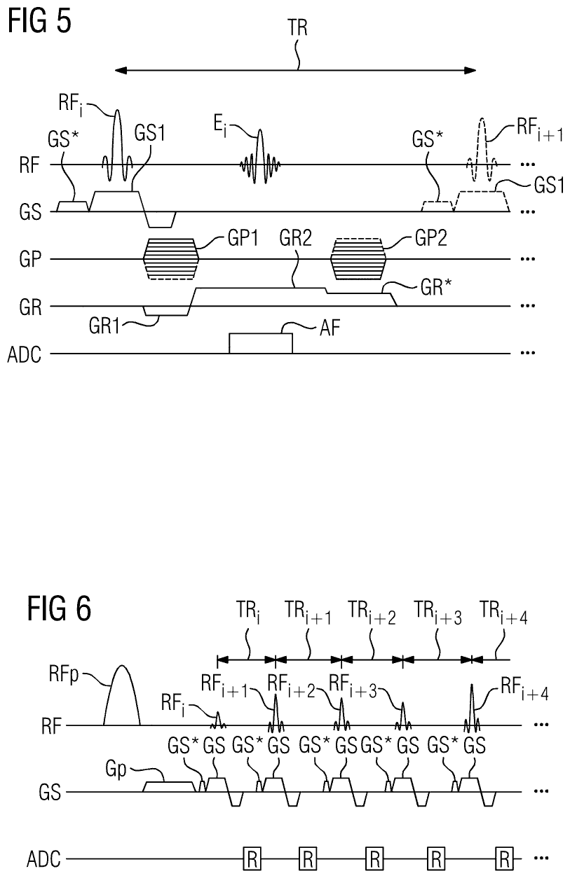

Preparation of the magnetization in the subject under examination can be performed first in this method (block 401). Preparation such as described later with reference to FIG. 6 is suitable in particular here.

After the preparation that may take place, a first (i=1) RF excitation pulse is applied to the subject under examination simultaneous with switching of a slice-selection gradient (block 403). The RF excitation pulse produces an echo signal Ei, which is acquired as measurement data MDi (block 405).

In addition to the slice-selection gradient already mentioned, further gradients, in particular for spatial encoding, are switched within one repetition time (=time between two successive RF excitation pulses) (block 407).

According to the invention, an additional dedicated dephasing gradient G* is also switched in this process, the effect of which is such that a transverse magnetization of the spins to be excited by an RF excitation pulse is dephased sufficiently, in particular fully, at the time at which each RF excitation pulse is applied.

In which direction, at what time and with what gradient moment the additional dedicated dephasing gradient G* is switched within a repetition time TR can be determined, for instance, by simulation or experimentally, taking into account conditions imposed, for example, by the hardware used or by desired properties of the acquired measurement values (block 415).

Image data BDi can be reconstructed from the measurement data MDi acquired for an echo signal Ei (block 409). This can also take place later.

If it is not yet the case that all the required RF excitation pulses have been applied (query 411, “n”), the process repeats from block 403 with a next RF excitation pulse being applied (i=i+1).

If a required number N of RF excitation pulses have already been applied (query 411, “y”), the measurement ends.

MRF methods can be used to compare the obtained series of N image data BDi (i=1 . . . N) with comparative data, for instance with a “dictionary” (block 413), in order to obtain for each pixel of the image data, quantitative parameter values for the subject under examination (e.g. T1 values, T2 values or B0 values or B1 values), from which parameter maps M can be produced.

FIG. 5 shows an example of a pulse sequence that can be used for the method according to the invention. Pulse sequence schemes illustrate the time waveform and timing of RF pulses to be applied and gradients to be switched, and also, if applicable, of acquisition activities (readout windows) and echo signals.

In the example in FIG. 5, the top line shows radio-frequency signals RF, the second line shows the gradient switching in the slice-selection direction, the third line shows the gradient switching in the phase encoding direction, the fourth line shows the gradient switching in the frequency encoding direction (readout direction), and the bottom line shows the readout activity ADC.

An RF excitation pulse RFi is applied simultaneous with switching of a slice-selection gradient GS1 in order to excite by the RF excitation pulse RFi only spins in a desired slice defined by the slice-selection gradient GS1 and the RF excitation pulse RFi.

Switching a gradient in the readout direction GR1 dephases the excited spins, i.e. a transverse magnetization present after the RF excitation pulse RFi fans out and thus collapses. A further gradient in the readout direction GS2, owing to its opposite polarization compared with the polarization of the first gradient in the readout direction GS1, causes the spins to re-phase, thereby producing the echo signal, known as a gradient echo, which is acquired during the switched gradient GR2 in a readout window AF, thereby ensuring frequency-encoding of the acquired signals. For the purpose of further spatial encoding, a gradient in the phase encoding direction GP1 is switched after the RF excitation pulse RFi and before the echo signal Ei is produced. In the example shown, various possible amplitudes of the gradient GP1 are shown at once, which can be applied progressively, for instance in successive repetitions of the series shown of RF pulses and gradients to be switched.

After the readout of the echo signal Ei, further gradients can be switched in the phase encoding direction GP2. These further gradients in the phase encoding direction GP2 in particular can have the same amplitude as the preceding gradient in the phase encoding direction GP1 but an opposite amplitude. A phase of the spins that is produced by the first gradient in the phase encoding direction GP1 is thereby “rotated back” again, with the result that any phase encoding in one repetition TR is not adopted in the subsequent repetition.

After a repetition time TR, a next RF excitation pulse RFi+1 is applied, which is made selective in the same manner in the slice direction by a slice-selection gradient GS1, and the scheme can be repeated using different spatial encoding by modified gradients in the phase encoding direction until all the required measurement data has been acquired.

So far, a typical Cartesian FISP sequence has been described. According to the invention, however, a dedicated dephasing gradient GS*, GR* is additionally switched, which specifically ensures that the transverse magnetization of the excited spins is sufficiently dephased before a subsequent RF excitation pulse RFi+1 is applied. It can be achieved thereby that the results of the measurement do not depend on the applied B0 field. Said dedicated dephasing gradient GS* can be switched in the slice selection direction GS. Given typically excited slice thicknesses of approximately 2 millimeters, the spatial resolution in the slice direction is generally lower than the spatial resolution in the plane that lies orthogonal to the slice direction, in which the pixel resolution typically is approximately 0.5 millimeters by 0.5 millimeters. Thus greater dephasing of the transverse magnetization can be achieved by a gradient in the slice selection direction than by an equally strong and equally long gradient in a direction orthogonal to the slice selection direction. Nonetheless, it may still be useful to switch the dedicated dephasing gradients in the readout direction GR* and/or the phase encoding direction (not shown). This can facilitate, for instance, a more even distribution of the load placed on the gradient coils acting in the various directions. It is also conceivable to distribute the dedicated dephasing gradients GS*, GR* over two or all three encoding directions (slice selection direction, phase encoding direction and readout direction).

It fundamentally makes sense here to switch the dephasing gradients GS*, GR* with the same polarity as adjacent gradients used for the spatial encoding. As a result, the gradients adjacent to the dephasing gradients GS*, GR* do not work against the desired dephasing but contribute constructively to the desired dephasing.

Dedicated dephasing gradients can be switched in a time window after a readout window AF and before the subsequent RF excitation pulse RFi+1. This minimizes an effect of the dedicated dephasing gradients on the spatial encoding of the measured echo signals.

FIG. 6 shows a larger portion of a more general pulse sequence that can be used for the method according to the invention. In this figure, the top line shows RF pulses to be applied, the second line shows gradients to be switched in the slice selection direction, and the bottom line shows the readout windows “R”, in which the measurement data acquisition takes place. Gradients that are switched in the phase encoding direction and in the readout direction (frequency encoding direction; not shown here) define the respective times after the preceding RF excitation pulse RFi after which an echo signal is formed, and define the k-space trajectories used for reading out the formed echo signals.

Gradients can be switched (activated) in the phase encoding direction and readout direction so as to produce a FISP sequence that uses spiral k-space sampling, for instance as described in the article by Jiang et al. cited above. It is also conceivable that the gradients are switched in the phase encoding direction and readout direction so as to produce a FISP sequence that uses Cartesian k-space sampling, for instance as described in FIG. 5. It is also conceivable that the gradients are switched in the phase encoding direction and readout direction so as to produce a FISP sequence that uses radial k-space sampling. Those k-space trajectories along which k-space is meant to be sampled during the readout of the echo signals can be made dependent, for example, on a required motion insensitivity, a required distribution in k-space and/or a required resolution.

In order to prepare the measurement, a preparation pulse RFp, for example, which manipulates the magnetization in the subject under examination in a desired manner, can be applied to the subject under examination. For example, the preparation pulse RFp may be an inversion pulse, which upsets possible equilibrium states of the magnetization. After said preparation pulse RFp, a preparation gradient Gp can be switched for further preparation of the magnetization. This preparation gradient Gp can be used in particular to dephase, and hence destroy, any transverse magnetization that may still exist after the preparation pulse RFp, so that any previously existing magnetization cannot have a negative impact on the subsequent elements of the pulse sequence.

As is standard practice in MRF measurements, n echo signals, which are acquired as the measurement data in readout windows “R”, are then generated, by applying N RF excitation pulses RFi (i=1 . . . N) and by switching gradients in the phase encoding direction and readout direction. In this process, in particular the repetition time TR and/or the flip angle that is produced by the RF excitation pulses RFi employed and through which a magnetization of the spins in the subject under examination is flipped by the applied RF excitation pulse, can be varied, as is shown in FIG. 6 by the different amplitudes of the RF excitation pulses and the different lengths of the repetition times TR.

A slice-selection gradient GS is switched (activated) during each RF excitation pulse RFi, so that the echo signals are produced in a desired slice of the subject under examination. In contrast with the pulse sequence scheme disclosed in the cited article by Jiang et al., in the example shown, however, dedicated dephasing gradients GS* according to the invention are switched before each RF excitation pulse RFi in order to make the measurement data acquired in the readout windows “R” actually independent of B0 field inhomogeneities. In all the figures, the dephasing gradients GS*, GS1*, GS2* are shown merely by way of example and may also be embodied differently, for instance attached to preceding or subsequent gradients.

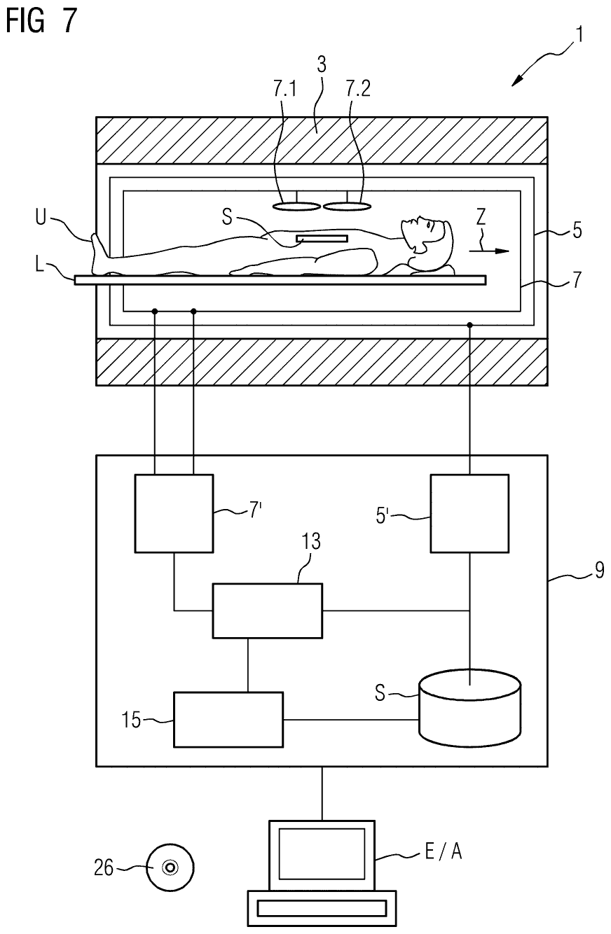

FIG. 7 shows schematically a magnetic resonance apparatus 1 according to the invention. This apparatus 1 has a scanner 3 that has a magnet for generating the basic magnetic field, a gradient unit 5 for generating the gradient fields, a radio-frequency unit 7 for emitting and receiving radio-frequency signals, and a control computer 9 designed to implement the method according to the invention. In FIG. 7, these sub-units of the magnetic resonance apparatus 1 are not shown in detail. In particular, the radio-frequency unit 7 may be formed by multiple coils (antennas) such as the coils 7.1 and 7.2 shown schematically, or more coils, which may either be designed solely to transmit radio-frequency signals or solely to receive the induced radio-frequency signals, or be designed to do both.

In order to examine a subject U under examination, for example a patient or else a phantom, the subject can be introduced into the measurement volume of the scanner 3 on a bed L. The slice S represents an example of a target volume of the subject under examination from which measurement data are to be acquired.

The control computer 9 controls the magnetic resonance apparatus 1 and in particular controls the gradient unit 5 by a gradient controller 5′ and controls the radio-frequency unit 7 by a radio-frequency transmit/receive controller 7′. The radio-frequency unit 7 can have a number of channels on which signals can be transmitted or received.

The radio-frequency unit 7 together with its radio-frequency transmit/receive controller 7′ is responsible for generating and radiating (transmitting) an alternating radio-frequency field for manipulating the spins in a region to be manipulated (for instance in slices S to be measured) of the subject U under examination. The center frequency of this alternating radio-frequency field, also referred to as the B1 field, is adjusted as much as possible so as to lie close to the resonant frequency of the spins to be manipulated. Off-resonance refers to deviations of the resonant frequency from the center frequency. In order to generate the B1 field, currents are applied to the RF coils, which currents are controlled in the radio-frequency unit 7 by the radio-frequency transmit/receive controller 7′.

In addition, the control computer 9 has a dephasing-gradient determination unit 15, which adds a suitable dedicated dephasing gradient according to the invention to a pulse sequence selected for acquiring measurement data. The control computer 9 is designed overall to perform a method according to the invention.

A processor 13 of the control computer 9 is designed to perform all the processing operations needed for the required measurements and determinations. Intermediate results and results required for this purpose or calculated in this process can be saved in a memory unit S of the control computer 9. The units shown need not necessarily be interpreted here as physically separate units but merely constitute a subdivision into logical units, which, however, can be implemented e.g. in fewer physical units or even in just one physical unit.

Via an input/output device E/A of the magnetic resonance apparatus 1 it is possible for a user, to enter control commands into the magnetic resonance apparatus 1 and/or to display results from the control computer 9, e.g. results such as image data.

As noted, the method described herein can be in the form of a non-transitory, electronically readable data storage medium 26 encoded with electronically readable control information (program code) that causes the control computer 9 to perform the described method when the data storage medium 26 is loaded into the control computer 9.

Although modifications and changes may be suggested by those skilled in the art, it is the intention of the Applicant to embody within the patent warranted hereon all changes and modifications as reasonably and properly come within the scope of the Applicant's contribution to the art.

1. A method for generating magnetic resonance measurement data from a subject comprising:
operating a magnetic resonance data acquisition scanner so as to execute a multi-repetition scan of the subject comprising, in each repetition (a) applying a radio-frequency (RF) excitation pulse to the subject, (b) activating a slice-selection gradient while the RF excitation pulse is being applied, (c) activating further gradients for spatial encoding, and (d) acquiring an echo signal, as measurement data, produced after the RF excitation pulse in the repetition, with said measurement data being spatially encoded by said further gradient; and
operating said magnetic resonance scanner to repeat (a) through (d) until a predetermined number of RF excitation pulses have been applied with, in each repetition, activating an additional dedicated rephasing gradient that causes a transverse magnetization of nuclear spins that were excited by the RF excitation pulse in that repetition to be dephased before each applied RF excitation pulse.

2. A method as claimed in claim 1 comprising acquiring said echo signals according to an FISP sequence acquisition.

3. A method as claimed in claim 1 wherein said slice-selection gradient is activated in a slice-selection direction, and activating said dedicated dephasing gradient in said slice-selection direction.

4. A method as claimed in claim 3 comprising activating said dedicated dephasing gradient in at least two directions of said spatial encoding, comprising a frequency encoding direction and a phase-encoding direction, in addition to said slice-selection direction.

5. A method as claimed in claim 1 comprising applying said RF excitation pulses so as to produce different flip angles in the respective repetitions, by which the applied RF excitation pulse in a respective repetition deflects a magnetization of nuclear spins in the subject.

6. A method as claimed in claim 1 comprising varying a repetition time of each repetition.

7. A method as claimed in claim 1 comprising entering the acquired measurement data into a memory organized as k-space along a k-space trajectory in said memory selected from the group consisting of a Cartesian trajectory, a spiral trajectory, and a radial trajectory.

8. A method as claimed in claim 1 comprising reconstructing image data from the acquired measurement data.

9. A method as claimed in claim 8 comprising implementing a magnetic resonance fingerprinting method to compare the reconstructed image data with data in a magnetic resonance fingerprinting dictionary, in order to produce a parameter map of said subject.

10. A method as claimed in claim 1 comprising determining said dedicated dephasing gradient by a simulation.

11. A method as claimed in claim 10 comprising determining said dedicated dephasing gradient by a Bloch equation simulation.

12. A method as claimed in claim 10 comprising experimentally verifying the dedicated dephasing gradient that was determined by simulation and, when necessary, modifying the dedicated dephasing gradient dependent on the experimental verification.

13. A method as claimed in claim 1 comprising experimentally determining said dedicated dephasing gradient.

14. A magnetic resonance apparatus comprising:
a magnetic resonance data acquisition scanner;
a computer configured to operate said magnetic resonance data acquisition scanner so as to execute a multi-repetition scan of the subject comprising, in each repetition (a) applying a radio-frequency (RF) excitation pulse to the subject, (b) activating a slice-selection gradient while the RF excitation pulse is being applied, (c) activating further gradients for spatial encoding, and (d) acquiring an echo signal, as measurement data, produced after the RF excitation pulse in the repetition, with said measurement data being spatially encoded by said further gradient; and
said computer being configured to operate said magnetic resonance scanner to repeat (a) through (d) until a predetermined number of RF excitation pulses have been applied with, in each repetition, activating an additional dedicated rephasing gradient that causes a transverse magnetization of nuclear spins that were excited by the RF excitation pulse in that repetition to be dephased before each applied RF excitation pulse.

15. A non-transitory, computer-readable data storage medium encoded with programming instructions, said storage medium being loaded into a computer of a magnetic resonance apparatus, comprising a magnetic resonance data acquisition scanner, said programming instructions causing said computer to:
operate the magnetic resonance data acquisition scanner so as to execute a multi-repetition scan of the subject comprising, in each repetition (a) applying a radio-frequency (RF) excitation pulse to the subject, (b) activating a slice-selection gradient while the RF excitation pulse is being applied, (c) activating further gradients for spatial encoding, and (d) acquiring an echo signal, as measurement data, produced after the RF excitation pulse in the repetition, with said measurement data being spatially encoded by said further gradient; and
operate said magnetic resonance scanner to repeat (a) through (d) until a predetermined number of RF excitation pulses have been applied with, in each repetition, activating an additional dedicated rephasing gradient that causes a transverse magnetization of nuclear spins that were excited by the RF excitation pulse in that repetition to be dephased before each applied RF excitation pulse.
